(19) United States
(12) Patent Application Publication
(10) Pub. No.: US 2024/0243554 A1
(43) Pub. Date: Jul. 18, 2024

(54) LIGHT SOURCE USING EPITAXIAL GROWTH AND METHOD OF MANUFACTURING THE LIGHT SOURCE

(71) Applicant: SAMSUNG ELECTRONICS CO., LTD., Suwon-si (KR)

(72) Inventors: Eunsung LEE, Suwon-si (KR); Junhee Choi, Suwon-si (KR); Kiho Kong, Suwon-si (KR); Joohun Han, Suwon-si (KR)

(73) Assignee: SAMSUNG ELECTRONICS CO., LTD., Suwon-si (KR)

(21) Appl. No.: 18/376,661

(22) Filed: Oct. 4, 2023

(30) Foreign Application Priority Data
Jan. 17, 2023 (KR) 10-2023-0006985
Feb. 9, 2023 (KR) 10-2023-0017570

(51) Int. Cl. H01S 5/323; H01S 5/028; H01S 5/40

(52) U.S. Cl. CPC H01S 5/323; H01S 5/0282; H01S 5/4087

(57) ABSTRACT

Provided is a light source including a plurality of support layers spaced apart from each other, an ionic crystalline layer on each of the plurality of support layers, a two-dimensional (2D) material layer on the ionic crystalline layer, and a light-emitting device including a first clad layer on the 2D material layer, a width of the first clad layer being greater than a width of the 2D material layer in a horizontal direction, an active layer on the first clad layer, and a second clad layer on the active layer and doped as a second conductive type electrically opposite to a first conductive type.

### CROSS-REFERENCE TO RELATED APPLICATIONS

This application is based on and claims priority under 35 U.S.C. § 119 to Korean Patent Application No. 10-2023-0006985, filed on Jan. 17, 2023, in the Korean Intellectual Property Office, and Korean Patent Application No. 10-2023-0017570, filed on Feb. 9, 2023, in the Korean Intellectual Property Office, the disclosures of which are incorporated by reference herein in their entireties.

### BACKGROUND

### 1. Field

The disclosure relates to a light source manufactured using remote epitaxial growth and a method of manufacturing the light source.

### 2. Description of Related Art

Forming a new monocrystalline layer on a monocrystalline substrate is referred to as epitaxial growth, and the formed new monocrystalline layer is referred to as an epitaxial layer. In epitaxial growth, the monocrystalline substrate and the epitaxial layer may include the same material (homoepitaxy) or a different material (heteroepitaxy), in both of which, however, a lattice constant of a material of the monocrystalline substrate and a lattice constant of a material of the epitaxial layer need to be the same as or similar to each other.

For epitaxial growth of a Group III-V light-emitting material having a large lattice constant difference, dislocation occurs, causing the efficiency of a device.

### SUMMARY

One or more example embodiments provide a light source manufactured using a remote epitaxy growth technique and a method of manufacturing the light source.

One or more example embodiments also provide a light wave detection and ranging (LiDAR) device including a light source manufactured using a remote epitaxy growth technique.

Additional aspects will be set forth in part in the description which follows and, in part, will be apparent from the description, or may be learned by practice of the presented embodiments of the disclosure.

According to an aspect of an example embodiment, there is provided a light source including a plurality of support layers spaced apart from each other, an ionic crystalline layer on each of the plurality of support layers, a two-dimensional (2D) material layer on the ionic crystalline layer, and a light-emitting device including a first clad layer on the 2D material layer, a width of the first clad layer being greater than a width of the 2D material layer in a horizontal direction, an active layer on the first clad layer, and a second clad layer on the active layer and doped as a second conductive type electrically opposite to a first conductive type.

The ionic crystalline layer may include a monocrystal of strontium titanium oxide (SrTiO₃), barium titanate (BaTiO₃), lithium fluoride (LiF), or aluminum nitride (AlN).

The 2D material layer may include at least one of graphene, boron nitride (BN), and a transition metal dichalcogenide.

The first clad layer may be on the plurality of support layers.

A thickness of the 2D material layer may be greater than or equal to 0.3 nm and less than or equal to 10 nm.

The light source may further include a passivation film adjacent to a side surface of each support layer of the plurality of support layers and a part of a top surface of the ionic crystalline layer.

The passivation film may include silicon oxide (SiO₂), silicon nitride (SiN), silicon oxynitride (SiOₓN_{y}), aluminum nitride (AlN), aluminum oxide (AlO₂), hafnium oxide (HfO₂), yttrium oxide (Y₂O₃), or titanium dioxide (TiO₂).

A thickness of each support layer of the plurality of support layers may be greater than or equal to 1 nm and less than or equal to 10 nm.

A distance between adjacent support layers among the plurality of support layers may be greater than or equal to 10 nm.

The first clad layer may include a p-type semiconductor material, and the second clad layer may include an n-type semiconductor material.

The light source may further include an insulating layer on a bottom surface of each support layer of the plurality of support layers, and a base layer a bottom surface of the insulating layer.

A thickness of the base layer may be greater than or equal to 100 nm and less than or equal to 500 nm.

The light-emitting device may include a laser diode.

The light-emitting device may include gallium arsenide (GaAs), gallium nitride (GaN), or indium phosphide (InP).

According to another aspect of an example embodiment, there is provided a light source including a substrate, an ionic crystalline layer on a top surface of the substrate, an insulating layer on a part of a top surface of the ionic crystalline layer, a plurality of two-dimensional (2D) material layers on the top surface of the ionic crystalline layer and electrically separated from each other by the insulating layer, and a plurality of light-emitting devices respectively on the plurality of 2D material layers, a width of each light-emitting device among the plurality of light-emitting devices being greater than a horizontal width of the 2D material layer.

The plurality of light-emitting devices may emit light of different colors.

The plurality of light-emitting devices may include GaAs, GaN, or InP.

The ionic crystalline layer may include a monocrystal of at least one of SrTiO₃, BaTiO₃, LiF, and AlN.

The 2D material layer may include at least one of graphene, boron nitride (BN), and a transition metal dichalcogenide.

According to yet another aspect of an example embodiment, there is provided a method of manufacturing a light source, the method including forming an ionic crystalline layer on a substrate that includes a base layer, an insulating layer, and a support layer, sequentially etching a part of the ionic crystalline layer and a part of the support layer, forming a passivation film adjacent to the ionic crystalline layer and the support layer, forming a two-dimensional (2D) material layer after exposing a part of the passivation film on the ionic crystalline layer, epitaxially growing a first clad layer on the 2D material layer in a horizontal direction and a vertical direction, sequentially forming an active layer and a second clad layer on the first clad layer, and etching the first clad layer, the active layer, and the second clad layer, wherein the etching is performed such that a width of the first clad layer, a width of the active layer, and a width of the second clad layer are greater than a width of the 2D material layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a configuration of a light source according to an example embodiment;

FIGS. 2A, 2B, 2C, 2D, 2E, 2F, 2G, 2H, 2I, and 2J are cross-sectional views showing a method of manufacturing a light source according to an example embodiment;

FIG. 3 is a cross-sectional view of a light source according to another example embodiment;

FIG. 4 is a block diagram showing a configuration of a light wave detection and ranging (LiDAR) device including a light source manufactured using remote epitaxial growth according to an example embodiment; and

FIGS. 5 and 6 are conceptual views of a vehicle to which a LiDAR device according to an example embodiment is applied.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinbelow, with reference to the accompanying drawings, a light source using epitaxial growth and a method of manufacturing the light source will be described in detail. In the drawings, like reference numerals denote like components, and sizes of components in the drawings may be exaggerated for convenience of explanation. In addition, embodiments to be described are merely examples, and various modifications may be made from such embodiments.

An expression such as “above” or “on” may include not only the meaning of “immediately on in a contact manner”, but also the meaning of “on in a non-contact manner”. Singular forms include plural forms unless apparently indicated otherwise contextually. When a portion is referred to as “comprises” a component, the portion may not exclude another component but may further include another component unless stated otherwise.

The use of the terms of “the above-described” and similar indicative terms may correspond to both the singular forms and the plural forms. When there is an explicit description of the order of operations of the method or there is no description contrary thereto, these operations may be performed in an appropriate order and the order is not necessarily limited to the described order.

Connections of lines or connection members between components shown in the drawings are illustrative of functional connections and/or physical or circuit connections, and in practice, may be represented as alternative or additional various functional connections, physical connections, or circuit connections.

The use of all examples or exemplary terms is only to describe technical spirit in detail, and the scope is not limited by these examples or terms unless limited by the claims.

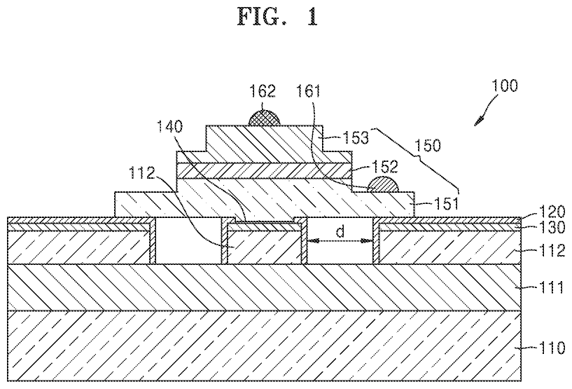

FIG. 1 is a cross-sectional view showing a configuration of a light source according to an example embodiment.

Referring to FIG. 1, a light source 100 may include a base layer 110, an insulating layer 111, a plurality of support layers 112, an ionic crystalline layer 130 arranged on the plurality of support layers 112, a two-dimensional (2D) material layer 140 arranged on the ionic crystalline layer 130, and a light-emitting device 150.

The base layer 110 may include, for example, crystalline silicon, monocrystalline silicon, doped silicon, or intrinsic silicon. A thickness of the base layer 110 may be, for example, greater than or equal to about 100 nm and less than or equal to about 500 nm.

The insulating layer 111 may be arranged on the base layer 110. The insulating layer 111 may include, for example, silicon dioxide.

The plurality of support layers 112 may be arranged on the insulating layer 111. The support layer 112 may include, for example, crystalline silicon, monocrystalline silicon, doped silicon, or intrinsic silicon. The support layer 112 may have a face-centered cubic (FCC) structure. A thickness of the support layer 112 may be, for example, greater than or equal to about 1 nm and less than or equal to about 10 nm. The thickness of the support layer 112 may be, for example, greater than or equal to about 1 nm and less than or equal to about 2 nm. A distance d between the plurality of support layers 112 may be, for example, greater than or equal to about 10 nm and less than or equal to about 100 nm. As the plurality of support layers 112 are spaced apart from each other with a certain distance therebetween, interference between the plurality of support layers may be minimized.

The base layer 110, the insulating layer 111, and the support layer 112 in combination may be referred to as a silicon on insulator (Sol) substrate. The insulating layer 111 may be arranged between the support layer 112 and the base layer 110 on the Sol substrate to remove an influence of the base layer 110 on the support layer 112, thereby improving the efficiency and characteristics of the support layer 112. However, embodiments are not limited thereto, and the Sol substrate combining the base layer 110, the insulating layer 111, and the support layer 112 may be replaced with, for example, a sapphire (Al₂O₃) substrate, a silicon carbide (SiC) substrate, a silicon (Si) substrate, or a gallium arsenide (GaAs) substrate.

The ionic crystalline layer 130 arranged on the support layer 112 may include a monocrystal of a Group III-V compound semiconductor having an ionic bond feature or an ionic crystal. The ionic crystalline layer 130 may be arranged on each of the plurality of support layers 112. The ionic crystalline layer 130 may include, for example, a monocrystal of strontium titanium oxide (SrTiO₃), barium titanate (BaTiO₃), lithium fluoride (LiF), or aluminum nitride (AlN).

A passivation film 120 may prevent current from flowing through the support layer 112 and a side of the ionic crystalline layer 130. The passivation film 120 may protect the support layer 112 and the ionic crystalline layer 130. The passivation film 120 may surround a side wall of the support layer 112 and a part of a top surface of the ionic crystalline layer 130. The passivation film 120 may be partially arranged on the top surface of the ionic crystalline layer 130 on which the light-emitting device 150 is initially grown. For example, the passivation film 120 may not be arranged in a central portion of the ionic crystalline layer 130 on which growth of the light-emitting device 150 is to start. The passivation film 120 may be arranged on the entire top surface of another ionic crystalline layer 130 on which growth of the light-emitting device 150 does not start. The passivation film 120 may have, for example, a thickness of about 10 nm or greater and about 50 nm or less. The passivation film 120 may include materials having insulating properties, e.g., a silicon oxide (SiOₓ), a silicon nitride (SiNₓ), a silicon oxynitride (SiOₓN_{y}), an aluminum nitride (AlN), an aluminum oxide (AlOₓ), a hafnium oxide (HfO₂), an yttrium oxide (Y₂O₃), a titanium dioxide (TiO₂), etc.

The 2D material layer 140 may be arranged on a region of the ion crystalline layer 130 where the passivation film 120 does not exist. For example, the 2D material layer 140 may be arranged on the top surface of the ionic crystalline layer 130 on which the light-emitting device 150 is initially grown. The 2D material layer 140 may include 2D crystals having a hexagonal crystal system structure. The 2D material layer 140 may include, for example, graphene, boron nitride (BN), or a transition metal dichalcogenide that is a compound of transition metal and a chalcogen element. For example, the transition metal dichalcogenide may include molybdenum disulfide (MoS₂), tungsten disulfide (WS₂), tantalum disulfide (TaS₂), hafnium disulfide (HfS₂), rhenium disulfide (ReS₂), titanium disulfide (TiS₂), niobium disulfide (NbS₂), tin disulfide (SnS₂), molybdenum selenide (MoSe₂), tungsten selenide (WSe₂), tantalum selenide (TaSe₂), hafnium selenide (HfSe₂), rhenium selenide (ReSe₂), titanium selenide (TiSe₂), niobium selenide (NbSe₂), tin selenide (SnSe₂), molybdenum telluride (MoTe₂), tungsten telluride (WTe₂), tantalum telluride (TaTe₂), hafnium telluride (HfTe₂), rhenium telluride (ReTe₂), titanium telluride (TiTe₂), niobium telluride (NbTe₂), tin telluride (SnTe₂), etc. The 2D material layer 140 may be transferred as a monolayer, a bilayer, or a plurality of layers on the top surface of the ionic crystalline layer 130. The 2D material layer 140 may have, for example, a thickness of about 0.3 nm or greater and about 10 nm or less. The 2D material layer 140 may have, for example, a thickness of about 1 nm or greater and about 10 nm or less.

When the ionic crystalline layer 130 having a polarity based on an ionic bond exists under the 2D material layer 140, semiconductor crystals may be epitaxially grown on the 2D material layer 140. As the polarity of the ionic crystalline layer 130 becomes stronger, a force for inducing growth of the semiconductor crystals on the 2D material layer 140 may become stronger. Thus, semiconductor crystals having a certain crystalline structure in a crystalline orientation of the ionic crystalline layer 130 without being directly chemical-bonded to the ionic crystalline layer 130 thereunder may be grown on the 2D material layer 140. In this case, the semiconductor crystals grown on the 2D material layer 140 are not chemically bonded to the ionic crystalline layer 130 thereunder and stress may be relieved by the 2D material layer 140, resulting in a high-quality monocrystal having a relatively low dislocation density. Thus, by using the 2D material layer 140, a semiconductor monocrystal having a relatively large lattice constant difference from the support layer 112 may be grown with high quality.

The light-emitting device 150 may be arranged on the 2D material layer 140. The light-emitting device 150 may include a first clad layer 151, an active layer 152, and a second clad layer 153. The first clad layer 151, the active layer 152, and the second clad layer 153 may be sequentially formed.

The first clad layer 151 may be arranged on the 2D material layer 140 and extend in a horizontal direction to have a greater width than that of the 2D material layer 140. The first clad layer 151 may be grown in the horizontal direction as well as in a vertical direction.

The first clad layer 151 may be, for example, a p-type semiconductor of a first conductive type. The first clad layer 151 may include various Group III-V compound semiconductor materials doped as a p type. For example, the first clad layer 151 may include indium phosphide (InP), indium aluminum gallium nitride (InAlGaN), gallium nitride (GaN), aluminum gallium nitride (AlGaN), indium gallium nitride (InGaN), aluminum nitride (AlN), indium nitride (InN), or the like doped as the p type. The first clad layer 151 may be doped with magnesium (Mg), zinc (Zn), calcium (Ca), selenium (Se), barium (Ba), or the like. For example, the first clad layer 151 may be p-InP doped with p-type Mg.

The active layer 152 may include one quantum well or a multi-quantum well (MQW) in which a plurality of quantum wells and a plurality of walls are arranged alternately. When the active layer 152 includes a material of an MQW structure, the active layer 152 may have a structure where a plurality of quantum layers and a plurality of well layers are stacked alternately. The active layer 152 may include various Group III-V compound semiconductor materials. The active layer 152 may include, for example, InP, AlGaN, aluminum indium gallium nitride (AlInGaN), gallium arsenide (GaAs), GaN, etc.

The second clad layer 153 may be arranged on the active layer 152. The second clad layer 153 may be, for example, an n-type semiconductor having a second conductive type that is electrically opposite to a first conductive type. The second clad layer 153 may include any one or more of InP, InAlGaN, GaN, AlGaN, InGaN, AlN, and InN, doped as an n type. The second clad layer 153 may be doped with silicon (Si), germanium (Ge), tin (Sn), or the like. For example, the first clad layer 151 may be n-InP doped with n-type Si.

Horizontal widths of the first clad layer 151, the active layer 152, and the second clad layer 153 may be greater than widths of the 2D material layer 140 and the support layer 112 arranged thereunder. The first clad layer 151 may be arranged across the plurality of support layers 112 and supported by the plurality of support layers 112.

A first electrode 161 may be arranged on the first clad layer 151. The first electrode 161 may be a p-type electrode. A second electrode 162 may be arranged on the second clad layer 153. The second electrode 162 may be an n-type electrode. A contact layer may be arranged between the first clad layer 151 and the first electrode 161. The contact layer may be arranged between the second clad layer 153 and the second electrode 162.

As the size of the light-emitting device 150 is small, deformation caused by stress may have a large influence upon performance of the light-emitting device 150. According to an embodiment, occurrence of dislocation may be suppressed through remote epitaxial growth using the 2D material layer 140, thereby reducing defects and thus improving the light-emission efficiency of the light-emitting device 150.

The light-emitting device 150 of FIG. 1 may be a laser diode (LD). However, without being limited thereto, the light-emitting device 150 may include a light-emitting diode (LED).

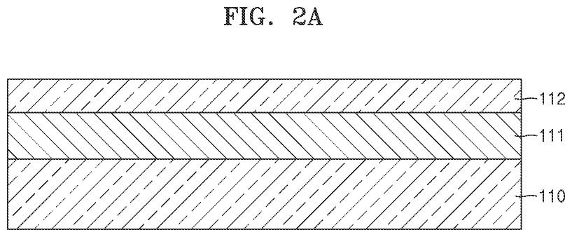

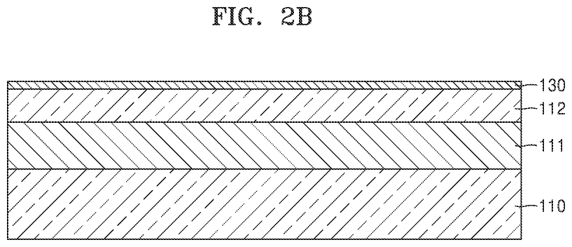

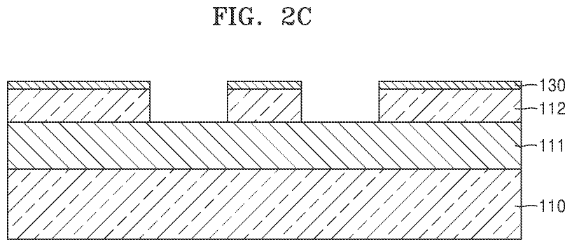

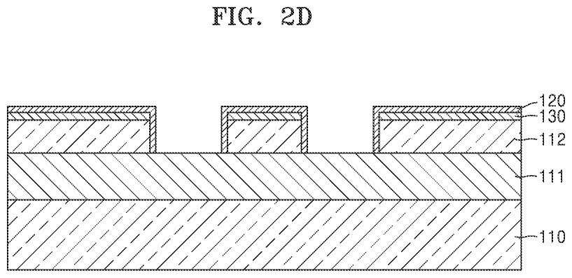

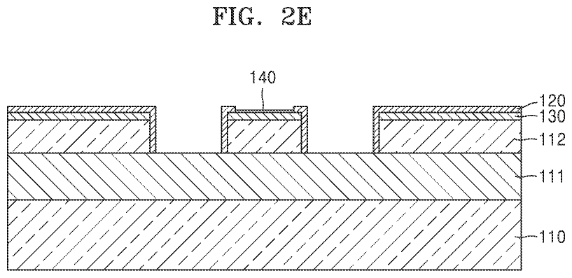

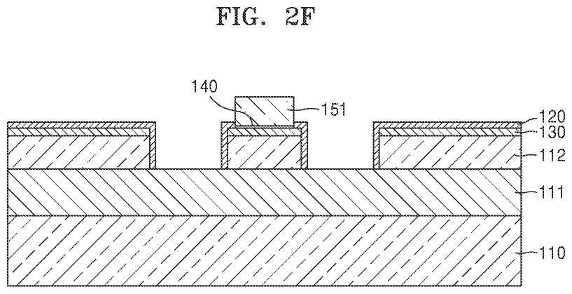

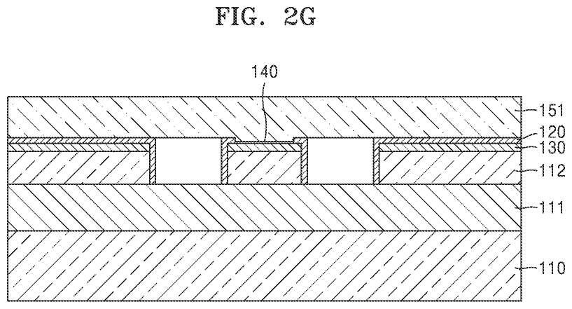

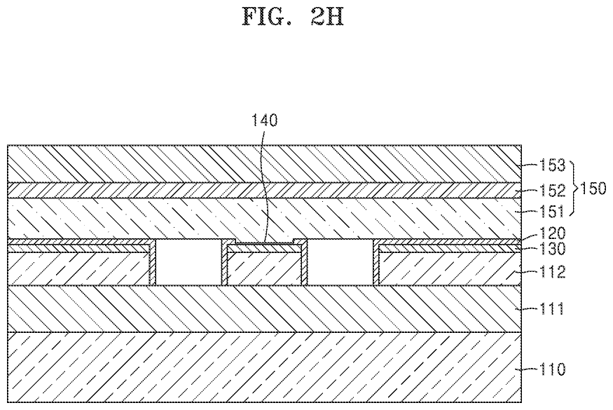

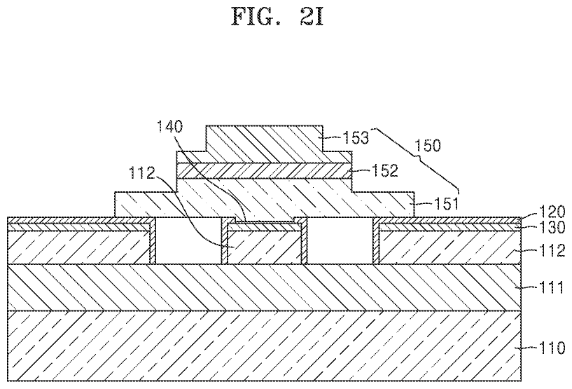

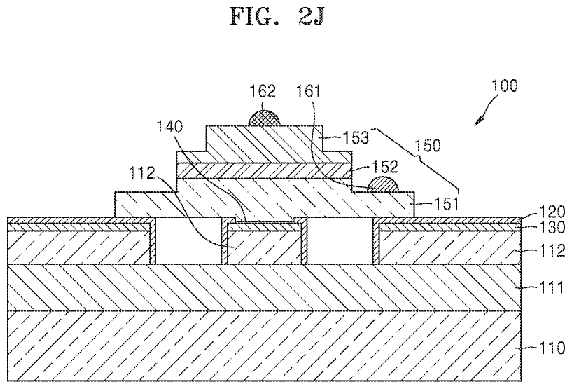

FIGS. 2A to 2I are cross-sectional views showing a method of manufacturing a light source according to an example embodiment.

Referring to FIG. 2A, the base layer 110 may be first provided, after which the insulating layer 111 may be formed on the top surface of the base layer 110 and the support layer 112 may be formed on the top surface of the insulating layer 111. The thickness of the base layer 110 may be, for example, greater than or equal to about 100 nm and less than or equal to about 500 nm. The thickness of the support layer 112 may be, for example, greater than or equal to about 1 nm and less than or equal to about 10 nm. The thickness of the support layer 112 may be, for example, greater than or equal to about 1 nm and less than or equal to about 2 nm.

Referring to FIGS. 2B and 2C, the ionic crystalline layer 130 may be formed on the support layer 112. Thereafter, a part of the ionic crystalline layer 130 and a part of the support layer 112 may be sequentially etched and removed. For example, the part of the ionic crystalline layer 130 and the part of the support layer 112 may be removed by photolithography and wet etching. An etched width may be greater than or equal to about 10 nm and less than or equal to about 100 nm.

Referring to FIG. 2D, the passivation film 120 may be formed to surround the ionic crystalline layer 130 and the support layer 112.

Referring to FIG. 2E, after the part of the passivation film 120 on the ionic crystalline layer 130 on which the first clad layer 151 described below is initially grown is exposed, the 2D material layer 140 may be formed. By exposing the passivation film 120 corresponding to a part where the first clad layer 151 described below is to be grown, selective growth may be possible.

Referring to FIG. 2F, the first clad layer 151 may be epitaxially grown on the 2D material layer 140. The first clad layer 151 may be grown to a certain thickness in the vertical direction. The first clad layer 151 may be grown, for example, by about 100 mm in the vertical direction.

Referring to FIG. 2G, the first clad layer 151 may be grown in the horizontal direction as well as in the vertical direction. The first clad layer 151 may have a greater width in the horizontal direction than a width of the 2D material layer 140 by growing in the horizontal direction.

Referring to FIG. 2H, the active layer 152 may be formed on the first clad layer 151. The active layer 152 may be grown in the horizontal direction as well as in the vertical direction. The active layer 152 may have a greater width in the horizontal direction than a width of the 2D material layer 140 by growing in the horizontal direction. The second clad layer 153 may be formed on the active layer 152. The second clad layer 153 may be grown in the horizontal direction as well as in the vertical direction.

Referring to FIG. 2I, the width of the light-emitting device 150 may be adjusted through etching. In this case, etching may be performed such that the width of the first clad layer 151 may be greater than a width of the active layer 152, which is greater than the width of the second clad layer 153. The horizontal width of the light-emitting device 150 may be greater than the width of the 2D material layer 140.

Referring to FIG. 2J, a first electrode 161 may be formed on the first clad layer 151 and a second electrode 162 may be formed on the second clad layer 153.

While FIGS. 2A to 2J show that one light-emitting device 150 is manufactured for convenience, the plurality of light-emitting devices 150 may be manufactured at a time and then separated into the plurality of light-emitting devices 150 in etching, without being limited thereto.

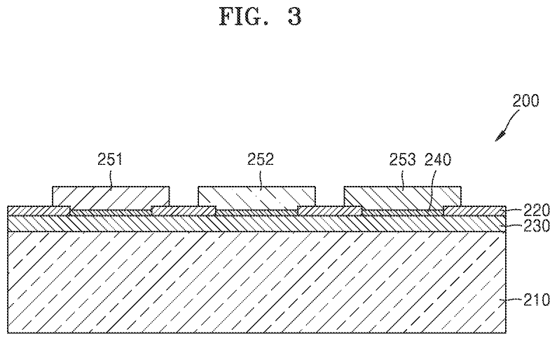

FIG. 3 is a cross-sectional view of a light source according to another example embodiment.

Referring to FIG. 3, a light source 200 may include a substrate 210, an ionic crystalline layer 230 arranged on a top surface of the substrate 210, an insulating layer 220 arranged on a part of the top surface of the ionic crystalline layer 230, a plurality of 2D material layers 240 arranged on the top surface of the ionic crystalline layer 230 and electrically separated from each other by the insulating layer 220, and a plurality of light-emitting devices 251, 252, and 253 respectively arranged on the plurality of 2D material layers 240. In the description of FIG. 3, description that is substantially the same as that of FIG. 1 is omitted.

The substrate 210 may include a sapphire (Al₂O₃) substrate, a silicon carbide (SiC) substrate, a silicon (Si) substrate, or a gallium arsenide (GaAs) substrate.

The insulating layer 220 may include silicon oxide (SiOₓ), silicon nitride (SiNₓ), silicon oxynitride (SiOₓN_{y}), aluminum nitride (AlN), aluminum oxide (AlOₓ), hafnium oxide (HfO₂), yttrium oxide (Y₂O₃), titanium dioxide (TiO₂), etc.

The plurality of light-emitting devices 251, 252, and 253 may have a width greater than the horizontal width of the 2D material layer 240. The plurality of light-emitting devices 251, 252, and 253 may include different semiconductor materials. For example, the plurality of light-emitting devices 251, 252, and 253 may include GaAs, GaN, or InP. The plurality of light-emitting devices 251, 252, and 253 may be configured to emit light of different colors.

The light source 200 may further include various optical devices arranged on the top surface of the substrate 101 as well as the plurality of light-emitting devices 251, 252, and 253.

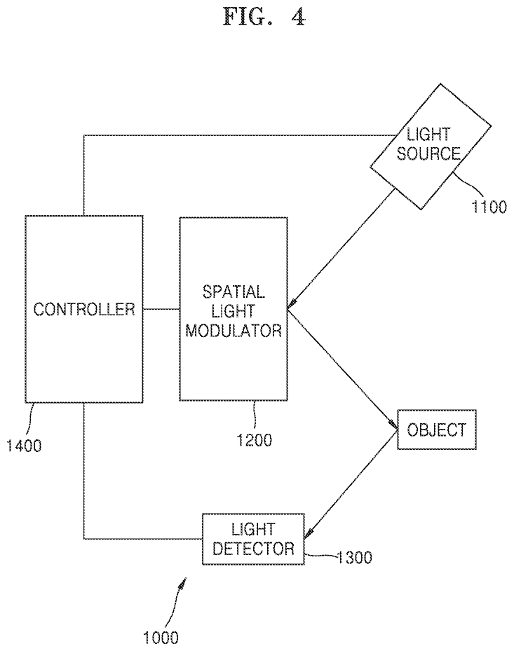

FIG. 4 is a block diagram schematically showing a structure of a light wave detection and ranging (LiDAR) device 1000 according to an example embodiment.

Referring to FIG. 4, the lidar device 1000 according to an embodiment may include a light source 1100 that emits light, a spatial light modulator 1200 that adjust the travelling direction of the light from the light source to an object to adjust a traveling direction of the light output from the light source 1100 toward the object, a light detector 1300 that detects light reflected from the object that is irradiated by light from the spatial light modulator 1200, and a controller 1400 that controls the spatial light modulator 1200.

The controller 1400 may include a computing device such as a workstation computer, a desktop computer, a laptop computer, or a tablet computer. The controller 1400 may include a simple controller, a microprocessor, a complex processor such as a central processing unit (CPU) or a graphics processing unit (GPU), a processor configured by software, or dedicated hardware or firmware. For example, the controller and the processor may be implemented by a general-use computer or an application-specific hardware component such as a digital signal processor (DSP), a field programmable gate array (FPGA), or an application-specific integrated circuit (ASIC).

The light source 1100 may include the light sources 100 of FIG. 1 or the light source 200 of FIG. 3. The light source 1100 may be, for example, an LD. However, without being limited thereto, the light source 1100 may include a light source or an LED that emits visible light.

The spatial light modulator 1200 may control the traveling direction of light by modulating a phase for each pixel. Phase modulation per pixel may be chronologically controlled, such that the traveling direction of light may be chronologically adjusted to scan an object. The spatial light modulator 1200 may be used as a beam steering device having high light efficiency and thus low power consumption.

The controller 1400 may control operations of the light source 1100, the spatial light modulator 1200, and the light detector 1300. For example, the controller 1400 may control on/off operations of the light source 1100 and the light detector 1300 and a beam scanning operation of the spatial light modulator 1200. The controller 1400 may also calculate information about an object based on a measurement result of the light detector 1300.

The LiDAR device 1000 of FIG. 4 may be a phase-shift or time-of-flight (ToF) device.

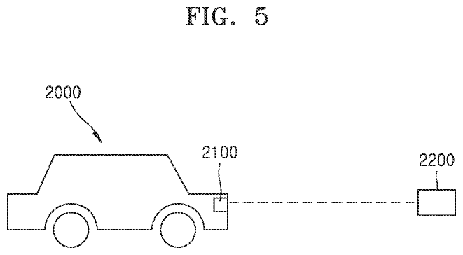

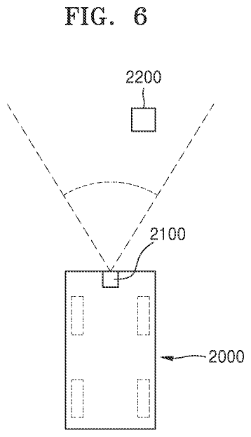

FIGS. 5 and 6 are conceptual views showing a case where a LiDAR device including a light-emitting device according to an example embodiment is applied to a vehicle. FIG. 5 is a view of the LiDAR device viewed from a side, and FIG. 6 is a view of the LiDAR device viewed from the top.

Referring to FIG. 5, a LiDAR device 2100 may be applied to a vehicle 2000, and information about a subject 2200 may be obtained using the LiDAR device 2100. The vehicle 2000 may be a vehicle having an autonomous driving function. By using the LiDAR device 2100, an object or a person, i.e., the subject 2200 in a direction in which the vehicle 2000 is moving may be detected. Moreover, a distance to the subject 2200 may be measured using information such as a time difference between a transmission signal and a detected signal, etc. As shown in FIG. 6, information about the nearby subject (the subject 2200) and a distant subject in a scanning range may be obtained.

Hence, according to example embodiments, a light source having improved efficiency of light emission may be provided due to strain relaxation by slip of a 2D material layer. While the light source using epitaxial growth and the method of manufacturing the light source have been described with reference to the embodiments described in the drawings, it will be understood by those of ordinary skill in the art that various modifications and equivalent other embodiments are possible therefrom. Therefore, the disclosed embodiments should be considered in a descriptive sense rather than a restrictive sense. The scope of the present specification is not described above, but in the claims, and all the differences in a range equivalent thereto should be interpreted as being included.

The light source according to the example embodiments may include a 2D material layer between an ionic crystalline layer and a light-emitting device and have the improved efficiency of light emission due to strain relaxation by slip of the 2D material layer.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. A light source comprising:
a plurality of support layers spaced apart from each other;
an ionic crystalline layer on each of the plurality of support layers;
a two-dimensional (2D) material layer on the ionic crystalline layer; and
a light-emitting device comprising:
a first clad layer on the 2D material layer, a width of the first clad layer being greater than a width of the 2D material layer in a horizontal direction;
an active layer on the first clad layer; and
a second clad layer on the active layer and doped as a second conductive type electrically opposite to a first conductive type.

2. The light source of claim 1, wherein the ionic crystalline layer comprises a monocrystal of strontium titanium oxide (SrTiO₃), barium titanate (BaTiO₃), lithium fluoride (LiF), or aluminum nitride (AlN).

3. The light source of claim 1, wherein the 2D material layer comprises at least one of graphene, boron nitride (BN), and a transition metal dichalcogenide.

4. The light source of claim 1, wherein the first clad layer is arranged across the plurality of support layers to be supported by the plurality of support layers.

5. The light source of claim 1, wherein a thickness of the 2D material layer is greater than or equal to 0.3 nm and less than or equal to 10 nm.

6. The light source of claim 1, further comprising a passivation film around a side surface of each support layer of the plurality of support layers and a part of a top surface of the ionic crystalline layer.

7. The light source of claim 6, wherein the passivation film comprises silicon oxide (SiO₂), silicon nitride (SiN), silicon oxynitride (SiOₓN_{y}), aluminum nitride (AlN), aluminum oxide (AlO₂), hafnium oxide (HfO₂), yttrium oxide (Y₂O₃), or titanium dioxide (TiO₂).

8. The light source of claim 1, wherein a thickness of each support layer of the plurality of support layers is greater than or equal to 1 nm and less than or equal to 10 nm.

9. The light source of claim 1, wherein a distance between adjacent support layers among the plurality of support layers is greater than or equal to 10 nm.

10. The light source of claim 1, wherein the first clad layer comprises a p-type semiconductor material, and
wherein the second clad layer comprises an n-type semiconductor material.

11. The light source of claim 1, further comprising:
an insulating layer on a bottom surface of each support layer of the plurality of support layers; and
a base layer a bottom surface of the insulating layer.

12. The light source of claim 11, wherein a thickness of the base layer is greater than or equal to 100 nm and less than or equal to 500 nm.

13. The light source of claim 1, wherein the light-emitting device comprises a laser diode.

14. The light source of claim 1, wherein the light-emitting device comprises gallium arsenide (GaAs), gallium nitride (GaN), or indium phosphide (InP).

15. A light source comprising:
a substrate;
an ionic crystalline layer on a top surface of the substrate;
an insulating layer on a part of a top surface of the ionic crystalline layer;
a plurality of two-dimensional (2D) material layers on the top surface of the ionic crystalline layer and electrically separated from each other by the insulating layer; and
a plurality of light-emitting devices respectively on the plurality of 2D material layers, a width of each light-emitting device among the plurality of light-emitting devices being greater than a horizontal width of the 2D material layer.

16. The light source of claim 15, wherein the plurality of light-emitting devices emit light of different colors.

17. The light source of claim 15, wherein the plurality of light-emitting devices comprise GaAs, GaN, or InP.

18. The light source of claim 15, wherein the ionic crystalline layer comprises a monocrystal of at least one of SrTiO₃, BaTiO₃, LiF, and AlN.

19. The light source of claim 15, wherein the 2D material layer comprises at least one of graphene, boron nitride (BN), and a transition metal dichalcogenide.

20. A method of manufacturing a light source, the method comprising:
forming an ionic crystalline layer on a substrate that comprises a base layer, an insulating layer, and a support layer;
sequentially etching a part of the ionic crystalline layer and a part of the support layer;
forming a passivation film adjacent to the ionic crystalline layer and the support layer;
forming a two-dimensional (2D) material layer after exposing a part of the passivation film on the ionic crystalline layer;
epitaxially growing a first clad layer on the 2D material layer in a horizontal direction and a vertical direction;
sequentially forming an active layer and a second clad layer on the first clad layer; and
etching the first clad layer, the active layer, and the second clad layer such that a width of the first clad layer, a width of the active layer, and a width of the second clad layer are greater than a width of the 2D material layer.
